(19) United States
(12) Patent Application Publication
(10) Pub. No.: US 2026/0353597 A1
(43) Pub. Date: Nov. 5, 2026

(54) Server System Cooling System

(71) Applicant: Dell Products L.P., Round Rock, TX (US)

(72) Inventors: Tung Yu Chien, New Taipei City (TW); Chien Tung Huang, New Taipei City (TW)

(21) Appl. No.: 19/198,421

(22) Filed: May 5, 2025

(51) Int. Cl. H05K 7/20

(52) U.S. Cl. CPC H05K 7/20145; H05K 7/20727

(57) ABSTRACT

An air flow system for use with a cooling system of an information handling system. The air flow system includes an air duct component; and, an air baffle component. The air baffle component includes an air flow portion, the air flow portion including a top wall component, a first side wall component and a second side wall component, the air flow portion being configured to be positioned on top of a rear portion of a component array; and, a mounting portion physically coupled to the air flow portion, the mounting portion including a top wall component, a first side wall component and a second side wall component; and wherein the air baffle component is positioned between the component array and the air duct component.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing an information handling system with a cooling system.

In one embodiment, the invention relates to an air baffle component of an air flow system for use with a cooling system of an information handling system, comprising: an air flow portion, the air flow portion including a top wall component, a first side wall component and a second side wall component, the air flow portion being configured to be positioned on top of a rear portion of a component array; and, a mounting portion physically coupled to the air flow portion, the mounting portion including a top wall component, a first side wall component and a second side wall component; and wherein the air baffle component is positioned between the component array and an air duct component.

In another embodiment, the invention relates to an air flow system for use with a cooling system of an information handling system comprising: an air duct component; and, an air baffle component, the air baffle component comprising: an air flow portion, the air flow portion including a top wall component, a first side wall component and a second side wall component, the air flow portion being configured to be positioned on top of a rear portion of a component array; and, a mounting portion physically coupled to the air flow portion, the mounting portion including a top wall component, a first side wall component and a second side wall component; and wherein the air baffle component is positioned between the component array and the air duct component.

In another embodiment, the invention relates to a system comprising: a chassis; a component array and a cooling system, the cooling system comprising a fan system and an air flow system, the air flow system comprising an air duct component; and, an air baffle component, the air baffle component comprising: an air flow portion, the air flow portion including a top wall component, a first side wall component and a second side wall component, the air flow portion being configured to be positioned on top of a rear portion of a component array; and, a mounting portion physically coupled to the air flow portion, the mounting portion including a top wall component, a first side wall component and a second side wall component; and wherein the air baffle component is positioned between the component array and the air duct component.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A, 4B, 4C and 4D, generally referred to as FIG. 4, show views of an air flow system.

FIGS. 5A, 5B, and 5C, generally referred to as FIG. 5, show views of an air flow system.

FIGS. 6A and 6B, generally referred to as FIG. 6, show views of an air duct mounting of an air flow system.

FIGS. 7A, 7B, 7C, 7D, 7E, 7F, 7G and 7H, generally referred to as FIG. 7, show views of an air flow system.

### DETAILED DESCRIPTION

Various aspects of the disclosure include an appreciation that it is known to provide server type information handling systems with cooling systems. Various aspects of the present disclosure include an appreciation that cooling systems often include fan systems, air flow systems, or a combination thereof. Various aspects of the present disclosure include an appreciation that known fan systems often include a plurality of fans mounted within a fan system housing. Various aspects of the present disclosure include an appreciation that known fan systems and air flow systems often direct cooling air across heat producing components of the server information handling system. Various aspects of the present disclosure include an appreciation that known air flow systems are often located downstream of the heat producing components.

Various aspects of the present disclosure include an appreciation that one example of a heat producing component is a graphics processing unit (GPU) module. Various aspects of the present disclosure include an appreciation that server type information handling systems are often configured with GPU platform which includes a plurality of GPU modules. Various aspects of the present disclosure include an appreciation that GPU modules have form factors defined by certain specifications. Various aspects of the present disclosure include an appreciation that one such specification is the peripheral component interconnect express (PCIe) card electromechanical (CEM) standard, often referred to as the PCIe CEM standard.

Various aspects of the present disclosure include an appreciation that the PCIe CEM standard defines a plurality of component form factors. Various aspects of the present disclosure include an appreciation that the PCIe CEM standard defines a GPU module form factor of up to substantially 12.3″. A GPU platform support multiple form factor type PCIe CEM cards up to the size 12.3″ max. a common PCIe CEM standard GPU module form factor is a double width card plus extender bracket form factor. Various aspects of the present disclosure include an appreciation that a common PCIe CEM standard GPU module form factor is a double width card plus extender bracket form factor often includes substantially 10.5″ cards plus an extender bracket to bring the entire depth of the GPU module to 12.3″. Various aspects of the present disclosure include an appreciation that GPU modules conforming to this form factor are often heavier such that the extender bracket is often not strong enough to pass shock and vibration test, often due to the rear alignment and constraint part not conforming to the heavier component. As a result, the bracket often deforms, a card edge card connector breaks, or a combination thereof.

Various aspects of the present disclosure include an appreciation that with certain known GPU platforms, a downstream air duct is often needed to guide airflow to downstream components (such as PCIE cards) to facilitate cooling of the downstream components. Various aspects of the present disclosure include an appreciation that with certain known GPU platforms, the downstream air duct is often mainly designed for 12.3 form factor components which can result in air flow bypass occurring when 10.5″ components are included within the GPU platform. Various aspects of the present disclosure include an appreciation that this air flow bypass can result in diminished downstream component cooling.

Various aspects of the present disclosure include an appreciation that with certain known GPU platforms, the extender bracket is provided with a top tab for mounting purposes. Various aspects of the present disclosure include an appreciation that certain mounting tabs can block power plug insertion to a rear power connector of a GPU module. Various aspects of the present disclosure include an appreciation that with certain GPU modules, providing screw mounting in the front of the component, constraint parts/features on top of the GPU module, or a combination thereof, still do not provide enough mounting strength to overcome shock and vibration impact of the GPU module.

A system and method are disclosed for providing a server system with a cooling system. In certain embodiments, the cooling system includes a fan system as well as an air flow system. In certain embodiments, the air flow system includes an air baffle component, an air duct component, or a combination thereof.

In certain embodiments, the air baffle component includes alignment features and constraint features. In certain embodiments, a portion of the air baffle component is positioned on top of a rear portion of the GPU modules. In certain embodiments, the air baffle component is positioned between the GPU modules and a downstream air duct component. In certain embodiments, the air baffle component fits within the gap a rear of a GPU module and an air duct component. In certain embodiments, the air baffle components modify air flow from the rear of a GPU module and the air duct component to minimize air flow bypass.

In certain embodiments, the air baffle component includes one or more gap filler ribs. In certain embodiments, the gap filler ribs fit within gaps between adjacent GPU modules contained within a GPU platform. In certain embodiments, the gap filler ribs constrain the movement range of the GPU modules such that the GPU modules can pass shock and vibration tests. In certain embodiments, the air baffle component allows an appropriate floating moving range to easily fit the plurality of gap filler ribs within gaps between GPU modules.

In certain embodiments, the air duct component is assembled onto an information handling system chassis. In certain embodiments, the air duct component is mounted to a power distribution component. In certain embodiments, the air duct component is mounted to a power distribution component via a plurality of fasteners.

Such an air flow system advantageously supports multiple GPU module form factors in a single chassis thereby gaining configuration efficiency.

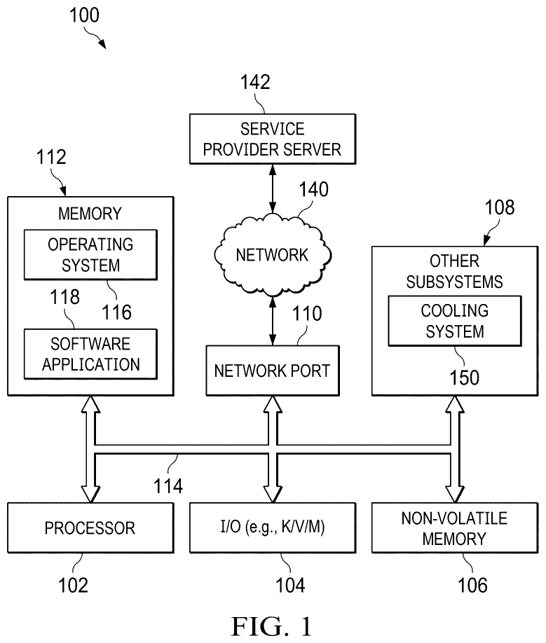

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a cooling system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more fan system 150 for cooling of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the cooling system 150 includes a fan system as well as an air flow system. In certain embodiments, the air flow system includes an air baffle component, an air duct component, or a combination thereof.

In certain embodiments, the air baffle component includes alignment features and constraint features. In certain embodiments, a portion of the air baffle component is positioned on top of a rear portion of the GPU modules. In certain embodiments, the air baffle component is positioned between the GPU modules and a downstream air duct component. In certain embodiments, the air baffle component fits within the gap a rear of a GPU module and an air duct component. In certain embodiments, the air baffle components modify air flow from the rear of a GPU module and the air duct component to minimize air flow bypass.

In certain embodiments, the air baffle component includes one or more gap filler ribs. In certain embodiments, the gap filler ribs fit within gaps between adjacent GPU modules contained within a GPU platform. In certain embodiments, the gap filler ribs constrain the movement range of the GPU modules such that the GPU modules can pass shock and vibration tests. In certain embodiments, the air baffle component allows an appropriate floating moving range to easily fit the plurality of gap filler ribs within gaps between GPU modules.

In certain embodiments, the air duct component is assembled onto an information handling system chassis. In certain embodiments, the air duct component is mounted to a power distribution component. In certain embodiments, the air duct component is mounted to a power distribution component via a plurality of fasteners.

Such an air flow system advantageously supports multiple GPU module form factors in a single chassis thereby gaining configuration efficiency.

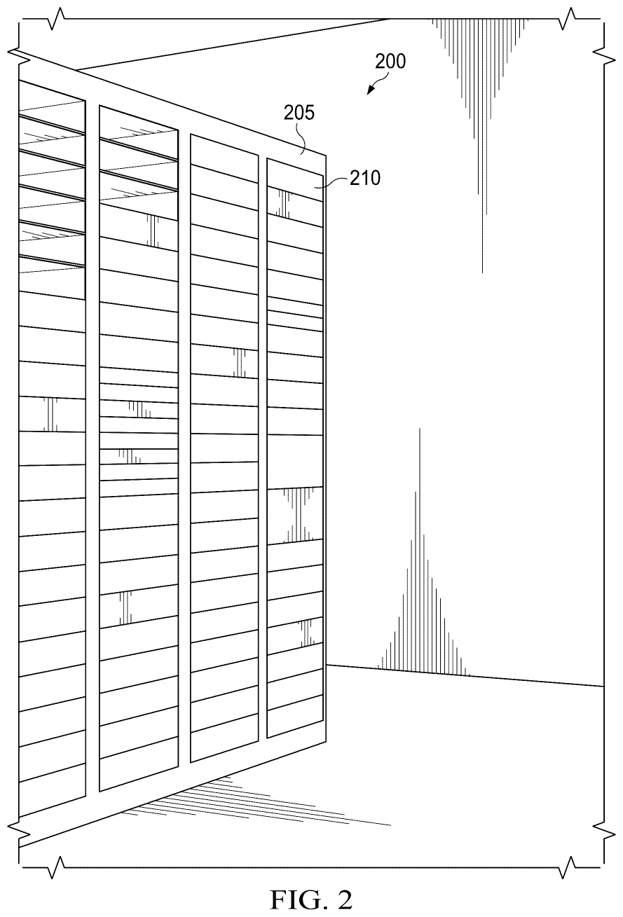

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

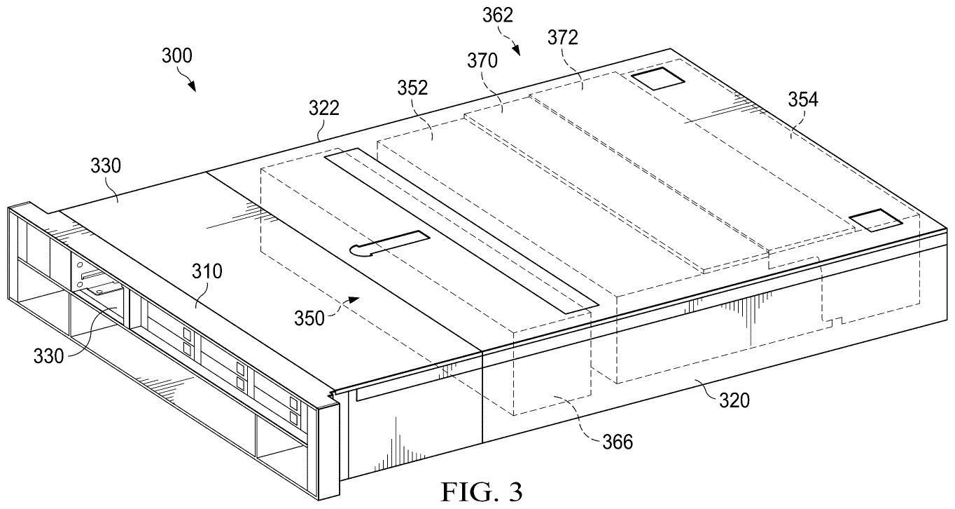

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a cooling system 350, a component array 352, a second component array 354, or a combination thereof. In certain embodiments, the cooling system 350 includes a fan system 360 as well as an air flow system 362. In certain embodiments, the air flow system 362 is positioned between the component array 352 and the second component array 354. In certain embodiments, the second component array 354 is positioned downstream of the component array 350 relative to the fan system 360. In certain embodiments, the component array 352 includes a GPU component array. In certain embodiments, the component array 354 includes a PCIe component array. In certain embodiments, the cooling system 350 corresponds to cooling system 150.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the air flow system 362 includes an air baffle component 370, an air duct component 372, or a combination thereof. In certain embodiments, the air baffle component 370 includes alignment features and constraint features. In certain embodiments, a portion of the air baffle component 370 is positioned on top of a rear portion of the component array 352. In certain embodiments, the air baffle component 370 is positioned between the component array 352 and a downstream air duct component 372. In certain embodiments, the air baffle component 370 fits within the gap a rear of one or more components of the component array 352 and the air duct component 372. In certain embodiments, the air baffle component 370 modifies air flow from the rear of the component array 352 and the air duct component 372 to minimize air flow bypass.

In certain embodiments, the air baffle component 370 includes one or more gap filler ribs. In certain embodiments, the gap filler ribs fit within gaps between adjacent components of the component array 352. In certain embodiments, the gap filler ribs constrain the movement range of the components such that the components can pass shock and vibration tests. In certain embodiments, the air baffle component 370 allows an appropriate floating moving range to easily fit the plurality of gap filler ribs within gaps between components of the component array 352.

In certain embodiments, the air duct component 372 is assembled within an information handling system 300. In certain embodiments, the air duct component 372 is mounted to a power distribution component. In certain embodiments, the air duct component 372 is mounted to a power distribution component via a plurality of fasteners.

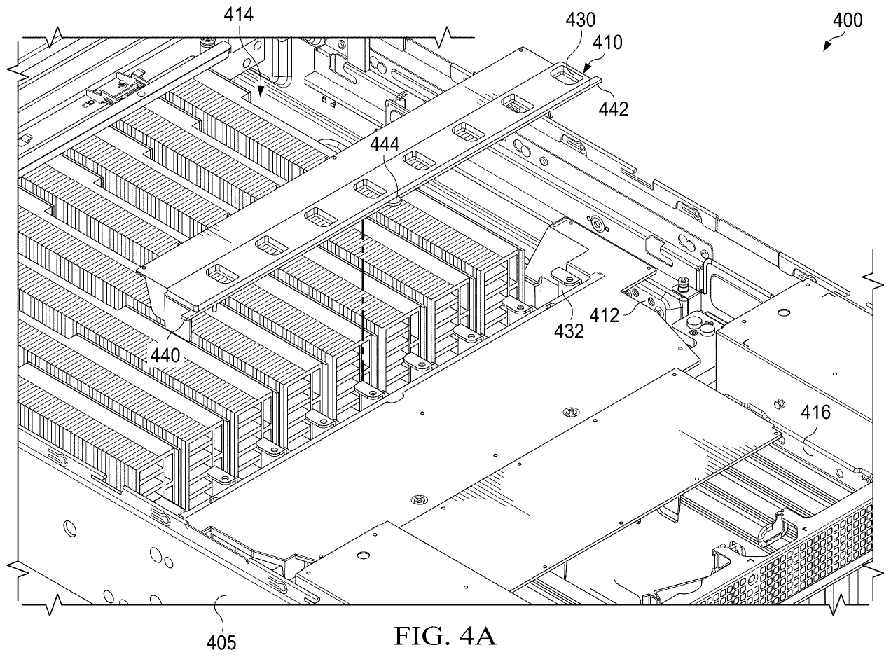

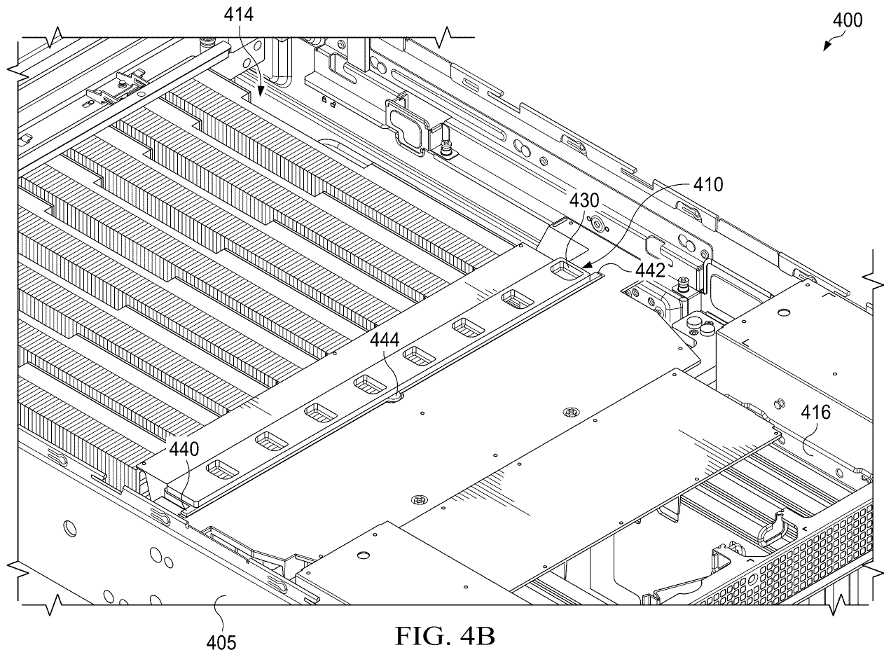

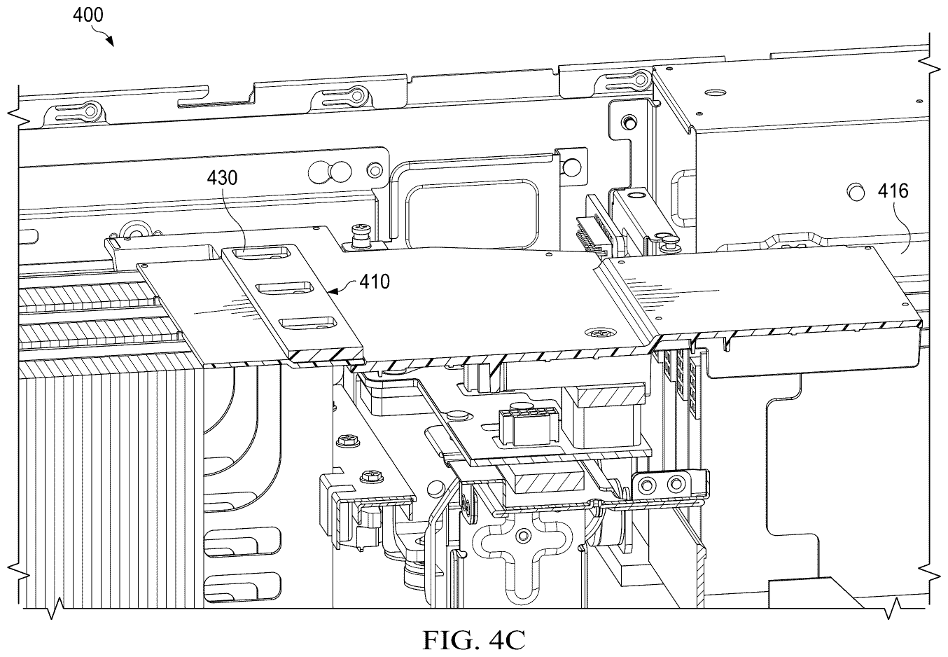

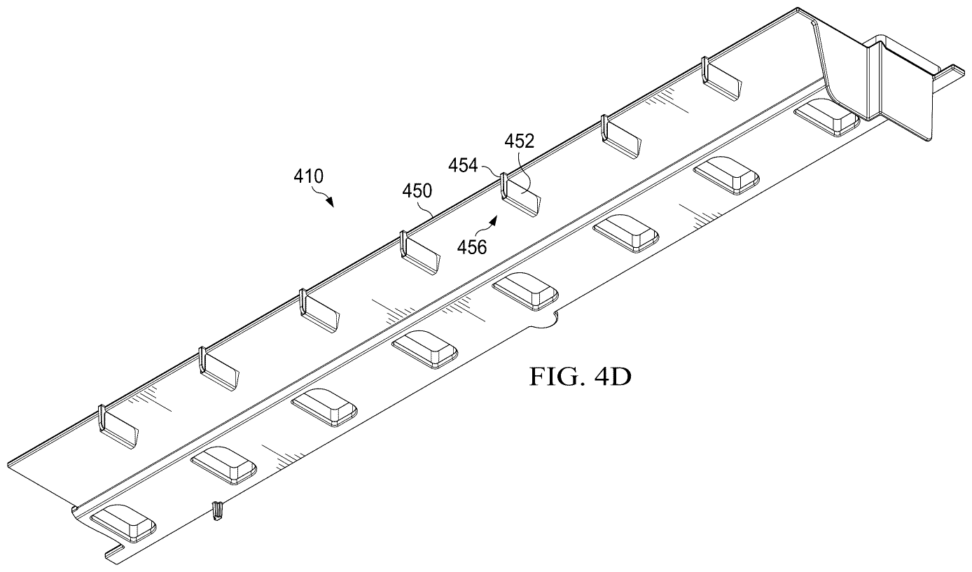

FIGS. 4A, 4B, 4C and 4D, generally referred to as FIG. 4, show views of an air flow system. More specifically, FIG. 4A shows a perspective view of a portion of server type information handling system 400 in which an air flow system 405 is mounted. FIG. 4B shows an exploded perspective view of an air flow system 405. FIG. 4C shows a cut away cross-sectional view of an air flow system 405. FIG. 4D shows a perspective view of a portion of an air baffle component 410 of an air flow system 405. In certain embodiments, the air flow system 405 corresponds to the air flow system of cooling system 150.

In certain embodiments, the air flow system 405 includes the air baffle component 410, an air duct component 412, or a combination thereof. In certain embodiments, the air baffle component 410 includes alignment features and constraint features. In certain embodiments, a portion of the air baffle component 410 is positioned on top of a rear portion of the component array 414. In certain embodiments, the air baffle component 410 is positioned between the component array 414 and a downstream air duct component 412. In certain embodiments, a portion of the air duct component 412 is positioned over a top of a downstream component array 416. In certain embodiments, the air baffle component 410 fits within the gap a rear of one or more components of the component array 414 and the air duct component 412. In certain embodiments, the air baffle component 410 modifies air flow from the rear of the component array 414 and the air duct component 412 to minimize air flow bypass.

In certain embodiments, the air baffle component 410 includes an air flow portion 420, a mounting portion 422, or a combination thereof. In certain embodiments, the air flow portion 420 is physically coupled to the mounting portion 422. In certain embodiments, the air flow portion 420 includes a top wall component, a first side wall component, a second side wall component, or a combination thereof. In certain embodiments, the first side wall component of the air flow portion 420 extends substantially (i.e., +/−20%) perpendicular from a first side of the top wall component of the air flow portion 420. In certain embodiments, the second side wall component of the air flow portion 420 extends substantially (i.e., +/−20%) perpendicular from a second side of the top wall component of the air flow portion 420. In certain embodiments, the mounting portion 422 includes a top wall component, a first side wall component, a second side wall component, or a combination thereof. In certain embodiments, the first side wall component of the mounting portion 422 extends substantially (i.e., +/−20%) perpendicular from a first side of the top wall component of the mounting portion 422. In certain embodiments, the second side wall component of the mounting portion 422extends substantially (i.e., +/−20%) perpendicular from a second side of the top wall component of the mounting portion 422. In certain embodiments, the top wall component of the air flow portion 420 extends substantially (i.e., +/−20%) parallel to top wall component of the mounting portion 422. In certain embodiments, a rear edge of the top wall component of the air flow portion 420 extends substantially (i.e., +/−20%) contiguous to front edge of the top wall component of the mounting portion 422.

In certain embodiments, the top wall component of the mounting portion 422 includes one or more mounting apertures 430. In certain embodiments, each of the one or more mounting apertures 430 are shaped as elongated ovals. In certain embodiments, each of the one or more mounting apertures 430 are configured to fit over a respective top tab 432 of a GPU module extender bracket. In certain embodiments, the air baffle component 410 is mounted to the top tabs 432 via respective fasteners (not shown).

In certain embodiments, the top wall component of the mounting portion 422 includes a first side alignment feature 440, a second side alignment feature 442, a central alignment feature 444, or a combination thereof. In certain embodiments, first side alignment feature 440 mates with a first side alignment recess defined by the air duct component 412. In certain embodiments, the second side alignment feature 442 mates with a second side alignment recess defined by the air duct component 412. In certain embodiments, the central alignment feature 444 mates with a central alignment recess defined by the air duct component 412.

In certain embodiments, the air baffle component 410 includes one or more gap filler ribs 450. In certain embodiments, the gap filler ribs 450 extend from an underside of the top wall component. In certain embodiments, each gap filler rib 450 includes a gap filler projection 452, a bulbous edge 454, or a combination thereof. In certain embodiments, the bulbous edge 454 extends beyond a rear edge of the top wall component of the air flow portion 420. In certain embodiments, the gap filler ribs 450 fit within gaps between adjacent components of the component array 414. In certain embodiments, the gap filler ribs 450 constrain the movement range of the components such that the components can pass shock and vibration tests. In certain embodiments, the air baffle component 410 allows an appropriate floating moving range to easily fit the plurality of gap filler ribs 450 within gaps between components of the component array 414.

In certain embodiments, the air duct component 412 is assembled within an information handling system 400. In certain embodiments, the air duct component 412 is mounted to a power distribution component. In certain embodiments, the air duct component 412 is mounted to a power distribution component via a plurality of fasteners.

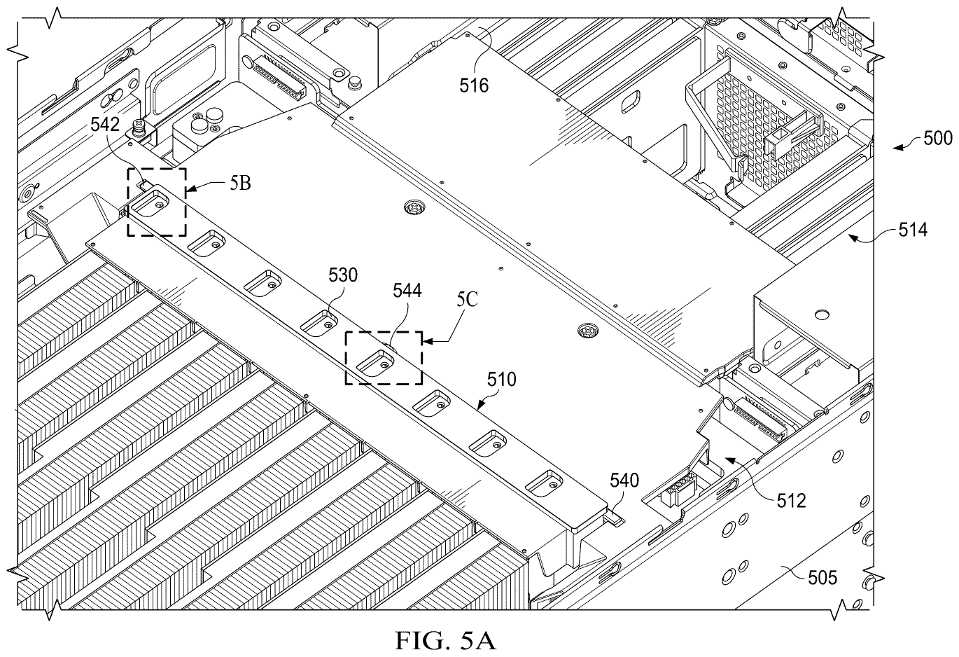

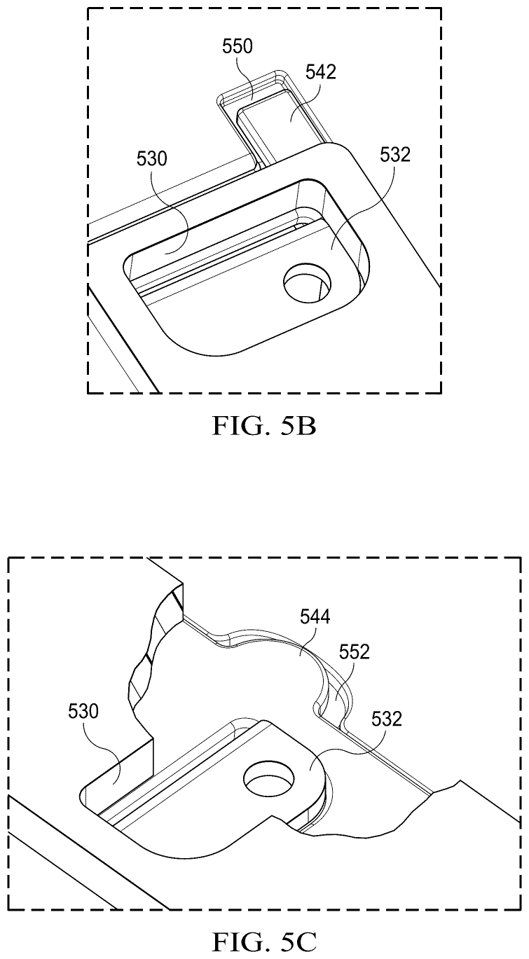

FIGS. 5A, 5B, and 5C, generally referred to as FIG. 5, show views of an air flow system. More specifically, FIG. 5A shows a perspective view of a portion of server type information handling system 500 in which an air flow system 505 is mounted. FIG. 5B shows a detailed perspective view of side alignment portion of an airflow system 505. FIG. 5C shows a detailed perspective view of side alignment portion of an airflow system 505. In certain embodiments, the air flow system 505 corresponds to the air flow system of cooling system 150.

In certain embodiments, the air flow system 505 includes the air baffle component 510, an air duct component 512, or a combination thereof. In certain embodiments, the air baffle component 510 includes alignment features and constraint features. In certain embodiments, a portion of the air baffle component 510 is positioned on top of a rear portion of the component array 514. In certain embodiments, the air baffle component 510 is positioned between the component array 514 and a downstream air duct component 512. In certain embodiments, a portion of the air duct component 512 is positioned over a top of a downstream component array 516. In certain embodiments, the air baffle component 510 fits within the gap a rear of one or more components of the component array 514 and the air duct component 512. In certain embodiments, the air baffle component 510 modifies air flow from the rear of the component array 514 and the air duct component 512 to minimize air flow bypass.

In certain embodiments, the air baffle component 510 includes an air flow portion 520, a mounting portion 522, or a combination thereof. In certain embodiments, the air flow portion 520 is physically coupled to the mounting portion 522. In certain embodiments, the air flow portion 520 includes a top wall component, a first side wall component, a second side wall component, or a combination thereof. In certain embodiments, the first side wall component of the air flow portion 520 extends substantially (i.e., +/−20%) perpendicular from a first side of the top wall component of the air flow portion 520. In certain embodiments, the second side wall component of the air flow portion 520 extends substantially (i.e., +/−20%) perpendicular from a second side of the top wall component of the air flow portion 520. In certain embodiments, the mounting portion 522 includes a top wall component, a first side wall component, a second side wall component, or a combination thereof. In certain embodiments, the first side wall component of the mounting portion 522 extends substantially (i.e., +/−20%) perpendicular from a first side of the top wall component of the mounting portion 522. In certain embodiments, the second side wall component of the mounting portion 522 extends substantially (i.e., +/−20%) perpendicular from a second side of the top wall component of the mounting portion 522. In certain embodiments, the top wall component of the air flow portion 520 extends substantially (i.e., +/−20%) parallel to top wall component of the mounting portion 522. In certain embodiments, a rear edge of the top wall component of the air flow portion 520 extends substantially (i.e., +/−20%) contiguous to front edge of the top wall component of the mounting portion 522.

In certain embodiments, the top wall component of the mounting portion 522 includes one or more mounting apertures 530. In certain embodiments, each of the one or more mounting apertures 530 are shaped as elongated ovals. In certain embodiments, each of the one or more mounting apertures 530 are configured to fit over a respective top tab 532 of a GPU module extender bracket. In certain embodiments, the air baffle component 510 is mounted to the top tabs 532 via respective fasteners (not shown).

In certain embodiments, the top wall component of the mounting portion 522 includes a first side alignment feature 540, a second side alignment feature 542, a central alignment feature 544, or a combination thereof. In certain embodiments, first side alignment feature 540 mates with a first side alignment recess 550 defined by the air duct component 512. In certain embodiments, the second side alignment feature 542 mates with a second side alignment recess defined by the air duct component 512. In certain embodiments, the central alignment feature 544 mates with a central alignment recess 552 defined by the air duct component 512. In certain embodiments, the side alignment recess 550, the central alignment recess 552, or a combination thereof, allow an appropriate floating moving range for the air baffle component 510 to easily fit the plurality of gap filler ribs within gaps between components of the component array 514.

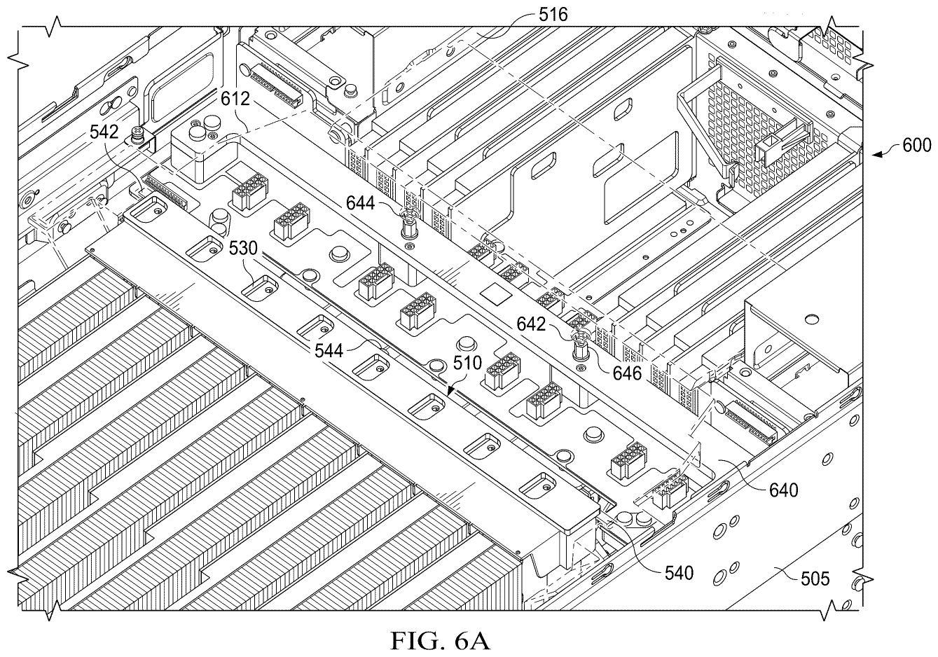

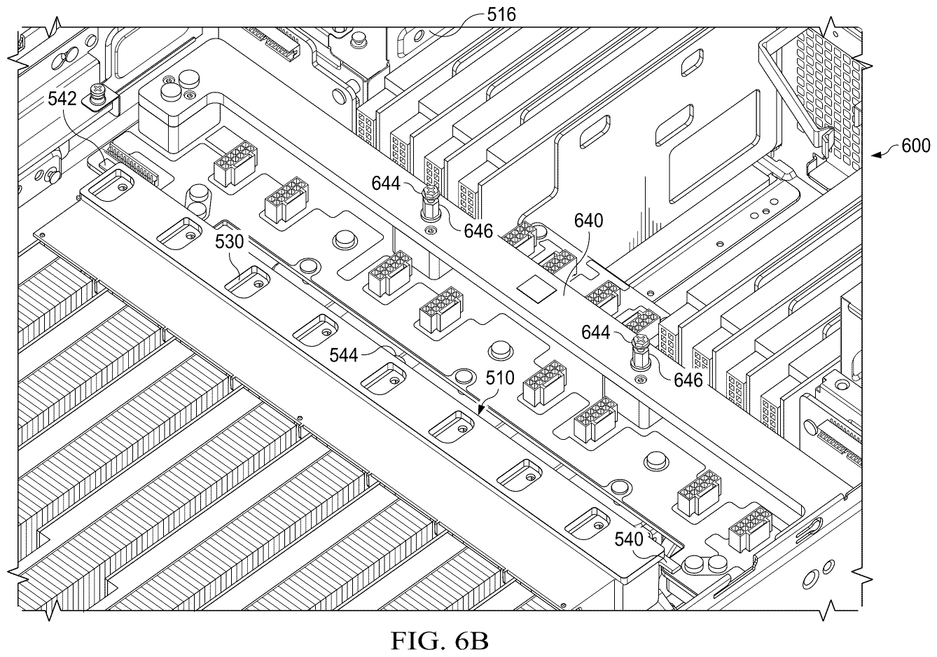

FIGS. 6A and 6B, generally referred to as FIG. 6, show views of mounting of an air flow system. More specifically, FIG. 6A shows a cut away perspective view of a portion of server type information handling system 600 in which an air flow system 605 is mounted. FIG. 6B shows a cut away perspective view of a portion of server type information handling system 600 in which an air flow system 605 is mounted. In certain embodiments, the air flow system 605 corresponds to the air flow system of cooling system 150.

In certain embodiments, the air duct component 612 is assembled within an information handling system 600. In certain embodiments, the air duct component 612 is mounted to a power distribution component 640 of the information handling system 600. In certain embodiments, the air duct component 612 defines one or more mounting aperture 642. In certain embodiments, the air duct component 612 is mounted to a power distribution component 640 via the one or more mounting apertures 642 and respective fasteners 644.

In certain embodiments, the power distribution component 640 includes one or more mounting posts 646. In certain embodiments, the one or more mounting posts 646 mate with respective mounting apertures 642.

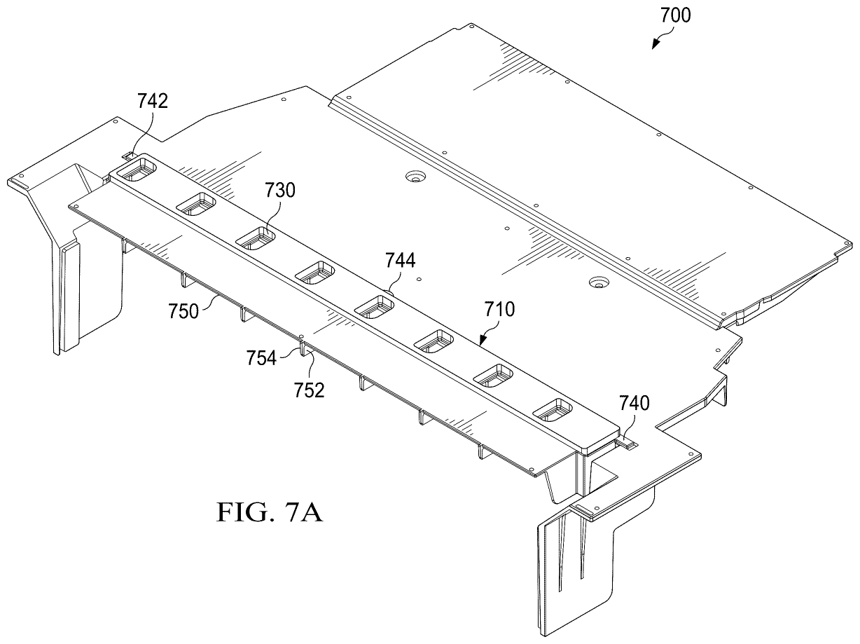

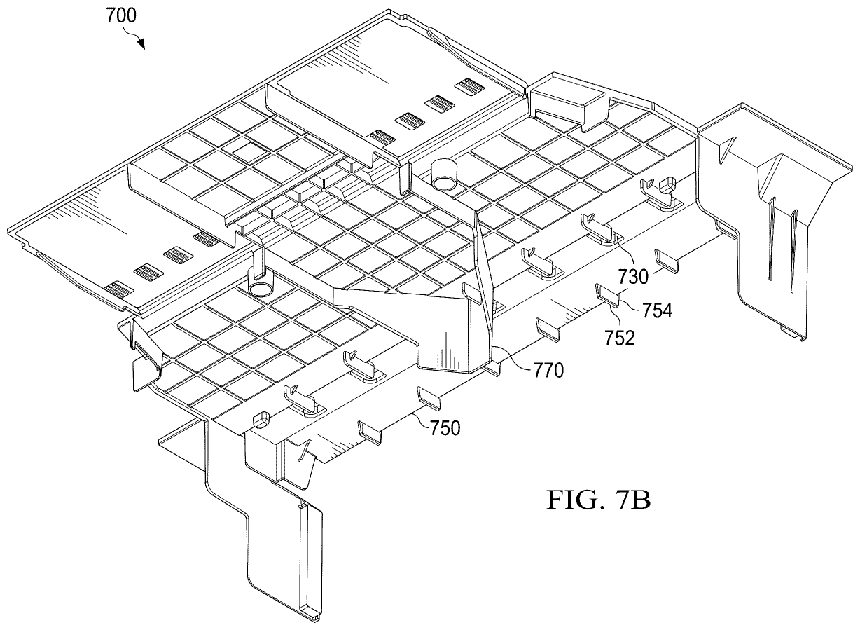

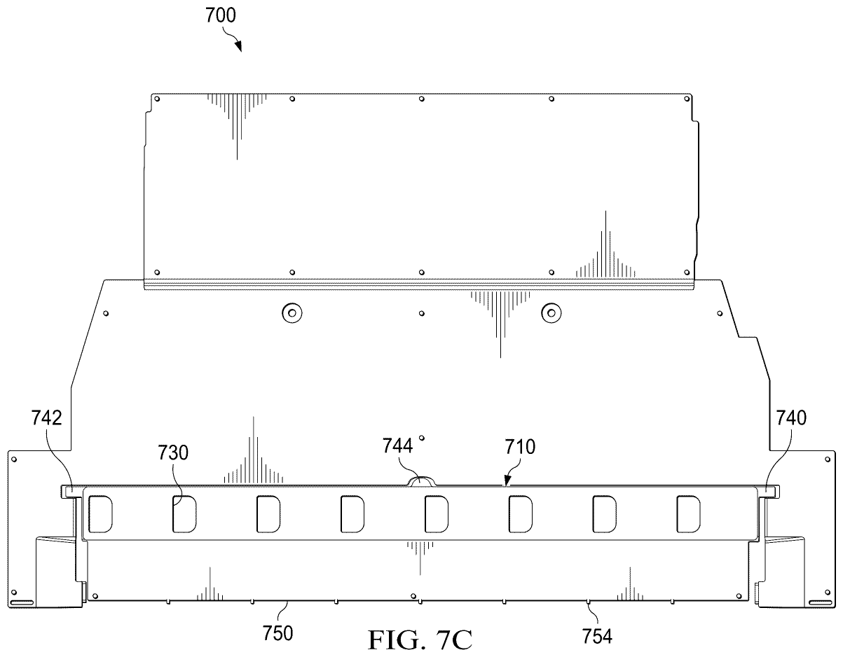

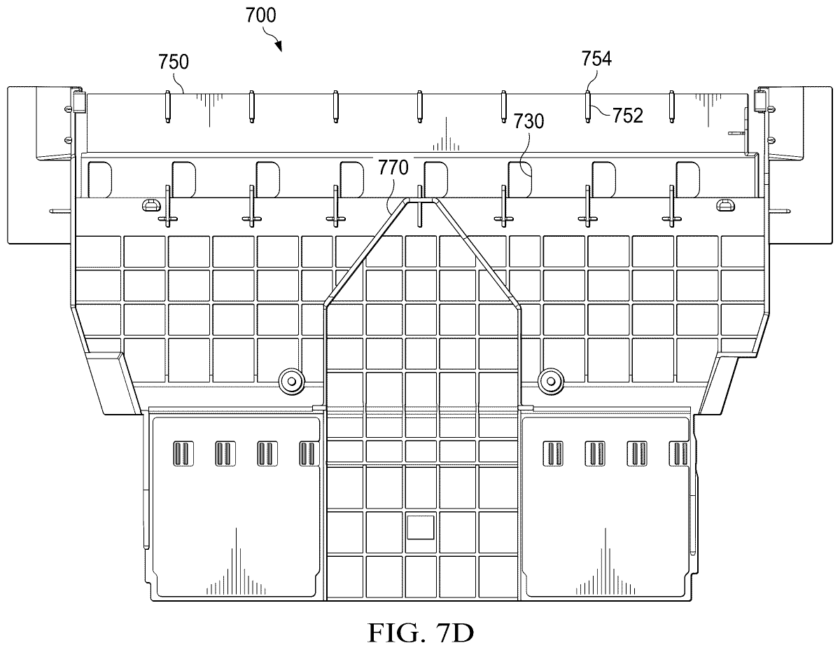

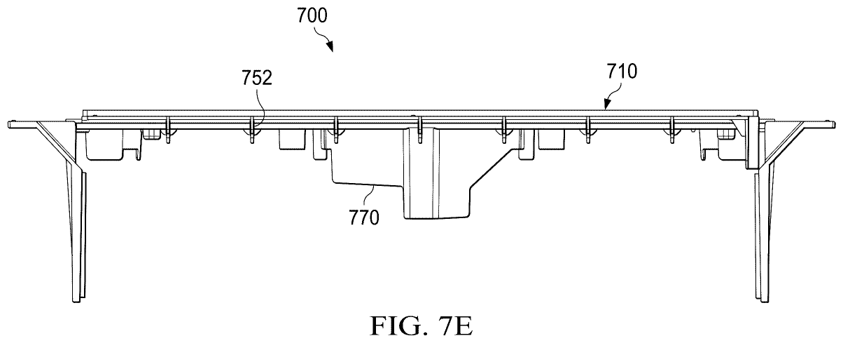

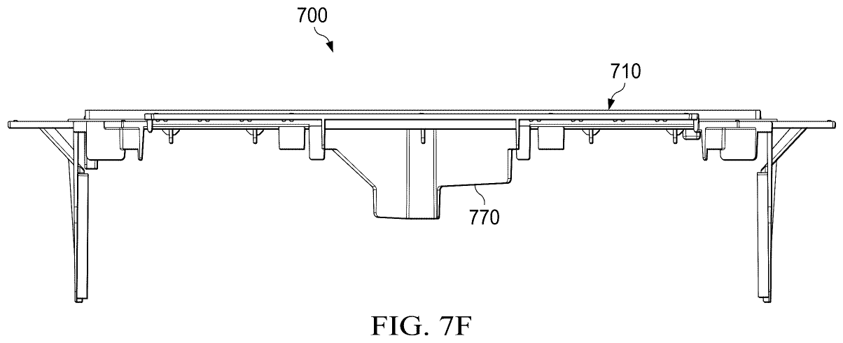

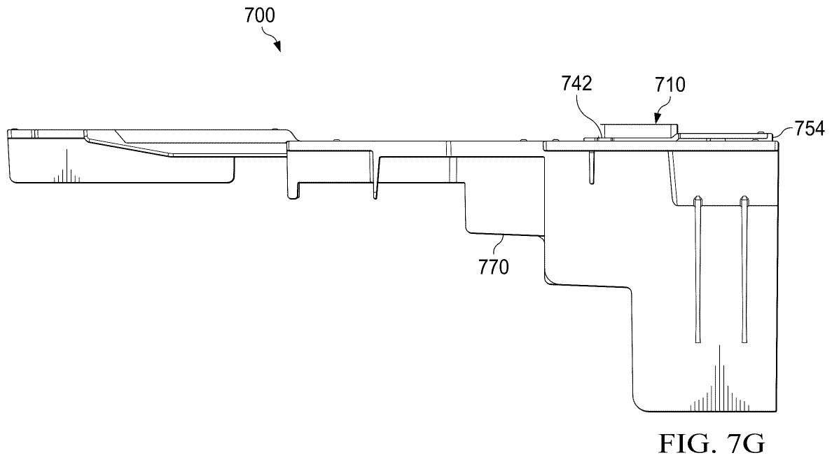

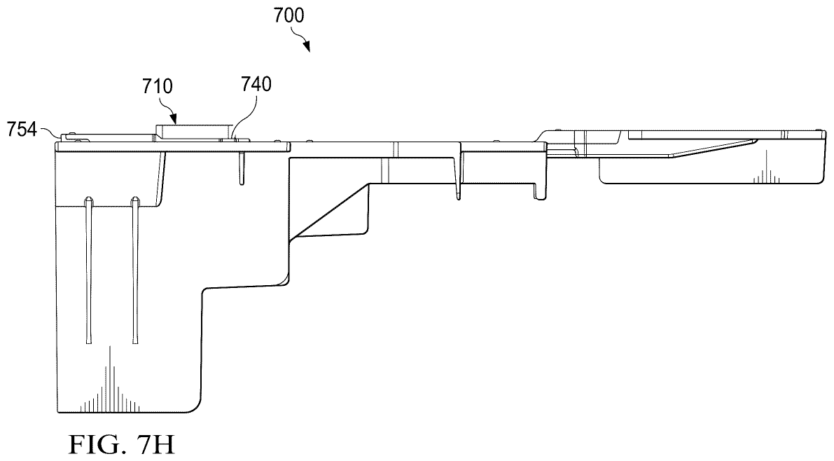

FIGS. 7A, 7B, 7C, 7D, 7E, 7F, 7G and 7H, generally referred to as FIG. 7, show views of an air flow system 700. More specifically, FIG. 7A shows a top perspective view of an air flow system 700. FIG. 7B shows a bottom perspective view of an air flow system 700. FIG. 7C shows a top view of an air flow system 700. FIG. 7D shows a bottom view of an air flow system 700. FIG. 7E shows a front view of an air flow system 700. FIG. 7F shows a rear view of an air flow system 700. FIG. 7G shows a left side view of an air flow system 700. FIG. 7H shows a right side view of an air flow system 700. In certain embodiments, the air flow system 700 corresponds to the air flow system of cooling system 150.

In certain embodiments, the air flow system 705 includes the air baffle component 710, an air duct component 712, or a combination thereof. In certain embodiments, the air baffle component 710 includes alignment features and constraint features. In certain embodiments, a portion of the air baffle component 710 is positioned on top of a rear portion of the component array 714. In certain embodiments, the air baffle component 710 is positioned between the component array 714 and a downstream air duct component 712. In certain embodiments, a portion of the air duct component 712 is positioned over a top of a downstream component array 716. In certain embodiments, the air baffle component 710 fits within the gap a rear of one or more components of the component array 714 and the air duct component 712. In certain embodiments, the air baffle component 710 modifies air flow from the rear of the component array 714 and the air duct component 712 to minimize air flow bypass.

In certain embodiments, the air baffle component 710 includes an air flow portion 720, a mounting portion 722, or a combination thereof. In certain embodiments, the air flow portion 720 is physically coupled to the mounting portion 722. In certain embodiments, the air flow portion 720 and the mounting portion 722 are constructed from a single piece of material. In certain embodiments, the air flow portion 720 includes a top wall component, a first side wall component, a second side wall component, or a combination thereof. In certain embodiments, the first side wall component of the air flow portion 720 extends substantially (i.e., +/−20%) perpendicular from a first side of the top wall component of the air flow portion 720. In certain embodiments, the second side wall component of the air flow portion 720 extends substantially (i.e., +/−20%) perpendicular from a second side of the top wall component of the air flow portion 720. In certain embodiments, the mounting portion 722 includes a top wall component, a first side wall component, a second side wall component, or a combination thereof. In certain embodiments, the first side wall component of the mounting portion 722 extends substantially (i.e., +/−20%) perpendicular from a first side of the top wall component of the mounting portion 722. In certain embodiments, the second side wall component of the mounting portion 722extends substantially (i.e., +/−20%) perpendicular from a second side of the top wall component of the mounting portion 722. In certain embodiments, the top wall component of the air flow portion 720 extends substantially (i.e., +/−20%) parallel to top wall component of the mounting portion 722. In certain embodiments, a rear edge of the top wall component of the air flow portion 720 extends substantially (i.e., +/−20%) contiguous to front edge of the top wall component of the mounting portion 722.

In certain embodiments, the top wall component of the mounting portion 722 includes one or more mounting apertures 730. In certain embodiments, each of the one or more mounting apertures 730 are shaped as elongated ovals. In certain embodiments, each of the one or more mounting apertures 730 are configured to fit over a respective top tab 732 of a GPU module extender bracket. In certain embodiments, the air baffle component 710 is mounted to the top tabs 732 via respective fasteners (not shown).

In certain embodiments, the top wall component of the mounting portion 722 includes a first side alignment feature 740, a second side alignment feature 742, a central alignment feature 744, or a combination thereof. In certain embodiments, first side alignment feature 740 mates with a first side alignment recess defined by the air duct component 712. In certain embodiments, the second side alignment feature 742 mates with a second side alignment recess defined by the air duct component 712. In certain embodiments, the central alignment feature 744 mates with a central alignment recess defined by the air duct component 712.

In certain embodiments, the air baffle component 710 includes one or more gap filler ribs 750. In certain embodiments, the gap filler ribs 750 extend from an underside of the top wall component. In certain embodiments, each gap filler rib 750 includes a gap filler projection 752, a bulbous edge 754, or a combination thereof. In certain embodiments, the bulbous edge 754 extends beyond a rear edge of the top wall component of the air flow portion 720. In certain embodiments, the gap filler ribs 750 fit within gaps between adjacent components of the component array 714. In certain embodiments, the gap filler ribs 750 constrain the movement range of the components such that the components can pass shock and vibration tests. In certain embodiments, the air baffle component 710 allows an appropriate floating moving range to easily fit the plurality of gap filler ribs 750 within gaps between components of the component array 714.

In certain embodiments, the air duct component 712 includes a central air flow guide component 770. In certain embodiments, the central air flow guide component 770 extends from an underside of the air duct component 712. In certain embodiments, the central air flow guide component 770 is configured to guide airflow to components within a second component array.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. An air baffle component of an air flow system for use with a cooling system of an information handling system, comprising:
an air flow portion, the air flow portion including a top wall component, a first side wall component and a second side wall component, the air flow portion being configured to be positioned on top of a rear portion of a component array; and,
a mounting portion physically coupled to the air flow portion, the mounting portion including a top wall component, a first side wall component and a second side wall component; and wherein
the air baffle component is positioned between the component array and an air duct component.

2. The air baffle component of claim 1, wherein:
the top wall component of the mounting portion defines a mounting aperture, the mounting aperture being configured to fit over a top tab of a component of the component array.

3. The air baffle component of claim 1, wherein:
the top wall component of the mounting portion includes a side alignment feature, the side alignment feature being configured to mate with a side alignment recess of the air duct component.

4. The air baffle component of claim 3, wherein:
the top wall component of the mounting portion includes a central alignment feature, the side alignment feature being configured to mate with a central alignment recess of the air duct component.

5. The air baffle component of claim 1, wherein:
the air flow portion includes a gap filler rib, the gap filler rib being configured to fit within a gap between adjacent components of the component array.

6. The air baffle component of claim 5, wherein:
the gap filler rib extends from an underside of the top wall component of the air flow portion.

7. An air flow system for use with a cooling system of an information handling system comprising:
an air duct component; and,
an air baffle component, the air baffle component comprising:
an air flow portion, the air flow portion including a top wall component, a first side wall component and a second side wall component, the air flow portion being configured to be positioned on top of a rear portion of a component array; and,
a mounting portion physically coupled to the air flow portion, the mounting portion including a top wall component, a first side wall component and a second side wall component; and wherein
the air baffle component is positioned between the component array and the air duct component.

8. The air flow system of claim 7, wherein:
the top wall component of the mounting portion defines a mounting aperture, the mounting aperture being configured to fit over a top tab of a component of the component array.

9. The air flow system of claim 7, wherein:
the top wall component of the mounting portion includes a side alignment feature, the side alignment feature being configured to mate with a side alignment recess of the air duct component.

10. The air flow system of claim 9, wherein:
the top wall component of the mounting portion includes a central alignment feature, the side alignment feature being configured to mate with a central alignment recess of the air duct component.

11. The air flow system of claim 7, wherein:
the air flow portion includes a gap filler rib, the gap filler rib being configured to fit within a gap between adjacent components of the component array.

12. The air flow system of claim 11, wherein:
the gap filler rib extends from an underside of the top wall component of the air flow portion.

13. A system comprising:
a chassis;
a component array; and,
a cooling system, the cooling system comprising
a fan system; and,
an air flow system, the air flow system comprising
an air duct component; and,
a air baffle component, the air baffle component comprising:
an air flow portion, the air flow portion including a top wall component, a first side wall component and a second side wall component, the air flow portion being configured to be positioned on top of a rear portion of a component array; and,
a mounting portion physically coupled to the air flow portion, the mounting portion including a top wall component, a first side wall component and a second side wall component; and wherein
the air baffle component is positioned between the component array and the air duct component.

14. The system of claim 13, wherein:
the top wall component of the mounting portion defines a mounting aperture, the mounting aperture being configured to fit over a top tab of a component of the component array.

15. The system of claim 13, wherein:
the top wall component of the mounting portion includes a side alignment feature, the side alignment feature being configured to mate with a side alignment recess of the air duct component.

16. The system of claim 15, wherein:
the top wall component of the mounting portion includes a central alignment feature, the side alignment feature being configured to mate with a central alignment recess of the air duct component.

17. The system of claim 13, wherein:
the air flow portion includes a gap filler rib, the gap filler rib being configured to fit within a gap between adjacent components of the component array.

18. The system of claim 17, wherein:
the gap filler rib extends from an underside of the top wall component of the air flow portion.
